(19) United States
(12) Patent Application Publication
(10) Pub. No.: US 2022/0097256 A1
(43) Pub. Date: Mar. 31, 2022

(54) Method for Producing or Modifying Silicon Carbide-Containing Articles

(71) Applicant: PSC Technologies GmbH, Berlin (DE)

(72) Inventors: Siegmund GREULICH-WEBER, Bad Lippspringe (DE); Rüdiger SCHLEICHER-TAPPESER, Berlin (DE)

(73) Assignee: PSC Technologies GmbH, Berlin (DE)

(21) Appl. No.: 17/423,630

(22) PCT Filed: Jan. 6, 2020
(86) PCT No.: PCT/EP2020/050118

§ 371 Date: Jul. 16, 2021

(30) Foreign Application Priority Data
Jan. 18, 2019 (DE) 10 2019 101 268.6

(51) Int. Cl. B28B 1/00; H01L 21/02; H01L 21/04; H01L 21/263; H01L 21/268; H01L 21/67; C01B 32/956; B33Y 10/00; B33Y 40/20; B33Y 30/00

(52) U.S. Cl. CPC B28B 1/001; H01L 21/02005; H01L 21/0455; H01L 21/2636; H01L 21/268; H01L 29/1608; C01B 32/956; B33Y 10/00; B33Y 40/20; B33Y 30/00; H01L 21/67115

(57) ABSTRACT

A method for making an article comprising silicon carbide. The method includes producing an article including silicon carbide via additive manufacturing. The method further includes heating via at least one laser beam in a site-selective and locally limited manner a surface of the article so as to cause at least one of ablation and chemical modification of the surface.

### CROSS-REFERENCE TO RELATED APPLICATIONS

This application is the U.S. national stage application of International Application No. PCT/EP2020/050118, filed Jan. 6, 2020, which International Application was published on Jul. 23, 2020, as International Publication WO 2020/148102 in the German language. The International Application claims priority to German Application No. 10 2019 101 268.6, filed Jan. 18, 2019. The International Application and German Application are hereby incorporated herein by reference in their entireties.

### FIELD

The present invention relates to the technical fields of additive manufacturing, as well as surface processing.

### BACKGROUND

In particular, the present invention relates to a method for the production or modification of silicon carbide-containing articles, as well as to articles obtainable by the method.

Further subject-matter of the present invention is an apparatus for carrying out the method.

Additive manufacturing processes are increasingly being used for the manufacture of articles in small batches or of individual pieces made of plastics or metallic materials. Additive manufacturing thereby permits both rapid and detailed, low-cost producing of articles from a variety of organic and inorganic materials.

What all additive manufacturing processes have in common is that the article to be produced is manufactured layer by layer on the basis of a 3D model, usually with the aid of CAD (Computer Aided Design). For inorganic materials, high-energy methods such as laser melting, electron beam melting or laser buildup welding are used, as only these can generate the high temperatures required to convert metals or ceramic materials into a melt.

A material of interest for both mechanical engineering and semiconductor technology due to its mechanical and electrical properties is silicon carbide.

Silicon carbide with the chemical formula SiC can be used in a variety of ways in electrical engineering as well as for producing ceramic materials. Due to its high hardness and high melting point, silicon carbide is also known as carborundum and is used as an abrasive or as an insulator in high-temperature reactors.

In addition, silicon carbide forms alloys or alloy-like compounds with a number of elements and compounds, which have a variety of advantageous material properties, such as high hardness, high durability, low weight and low oxidation sensitivity even at high temperatures.

Articles made of silicon carbide-containing materials are usually produced by sintering processes, wherein the silicon carbide articles obtained in this way comprise a relatively high porosity and are not suitable for many applications. Also, a detailed and high-resolution representation of in particular small components or articles based on silicon carbide-containing materials is difficult to achieve in this way.

SUMMARY

A first aspect of the present disclosure relates to methods for producing and/or modifying silicon carbide-containing articles.

Further subject-matter of the present disclosure relates to the silicon carbide-containing articles obtainable by methods of the present disclosure.

Yet further subject-matter of the present disclosure relate to apparatuses for carrying out the method according to the present disclosure.

It goes without saying that specific configurations mentioned below, in particular specific embodiments or the like, which are described only in the context of one aspect of the invention, also apply accordingly with respect to the other aspects of the invention, without this requiring express mention.

### BRIEF DESCRIPTION OF THE DRAWINGS

The figures show according to

FIG. 1A shows the structuring of the surface of a silicon carbide-containing article by ablation;

FIG. 1B shows the surface modification of a silicon carbide-containing article;

FIG. 2A shows the smoothing of the surface of a silicon carbide-containing article;

FIG. 2B shows the geometric processing of a silicon carbide-containing article;

FIG. 3 shows a silicon carbide-containing article with a chemically modified area;

FIG. 4 depicts an apparatus for carrying out the method according to the invention in an inkjet printing process;

FIG. 5 depicts a cross-section of an apparatus for carrying out the method according to the invention in the form of a powder bed process;

FIG. 6 is a sectional view of an apparatus for carrying out the method according to the invention in the form of laser deposition welding; and

FIG. 7 depicts one embodiment of an apparatus for carrying out the method according to the invention as laser deposition welding.

### DETAILED DESCRIPTION

Articles made of silicon carbide-containing materials are not accessible from silicon carbide powders in additive manufacturing because silicon carbide does not melt under normal pressure, but sublimes at temperatures of about 2,700° C. For producing articles containing silicon carbide by means of additive manufacturing, the procedure is therefore often such that organic polymers are presented in the form of the article to be produced by means of additive manufacturing and the body of organic polymer thus created is then pyrolyzed so that a carbon skeleton remains, which is infiltrated with silicon and finally converted to silicon carbide at high temperatures. This production method for articles containing silicon carbide is very costly and time-consuming, and thus not very efficient overall.

In the meantime, however, additive manufacturing processes for the direct production of silicon carbide-containing articles from suitable precursor materials are known, for example from DE 10 2015 105 085 A1, DE 10 2017 110 362 A1 or also DE 10 2017 110 361 A1. While DE 10 2015 105 085.4 and DE 10 2017 110 362 A1 describe the production of silicon carbide-containing articles from powdery precursors by means of a powder bed process—the so-called selective synthetic crystallization—DE 10 2017 110 361 A1 relies on liquid precursors. What the aforementioned methods have in common, however, is that the precursors are selectively and locally decomposed to the desired silicon carbide-containing materials under the action of laser radiation. With the previously mentioned additive manufacturing processes, it is possible to obtain a variety of silicon carbide-containing materials with excellent mechanical and/or electrical properties in the form of three-dimensional articles.

In the additive manufacturing processes described above, however, it is often necessary to rework the surfaces, for example to remove support structures or to smoothen the surface, which may comprise certain unevenness due to the layer-by-layer additive manufacturing. Such post-processing is usually carried out by subtractive methods for a wide range of materials.

Subtractive manufacturing processes are of particular importance for both surface engineering and processing, and in particular for shaping articles. Subtractive manufacturing processes are generally understood to be manufacturing processes in which material is removed from the surface of an article. Subtractive manufacturing processes are usually classic metal-cutting methods, such as grinding, drilling or milling. However, it is also possible to perform subtractive manufacturing using chemical methods, such as etching, or physical methods, such as laser radiation.

Subtractive methods are used to process a wide range of materials, for example to obtain the desired intermediate or end products from molded bodies or to impart desired surface contours and properties to an article.

While subtractive manufacturing methods are available in large numbers for many materials, for example metals, wood or even elemental silicon, and produce very good results, some ceramic materials, such as silicon carbide, are difficult to process using classic subtractive methods, in particular metal-cutting methods.

Furthermore, it is also generally problematic to structure silicon carbide surfaces in a targeted manner, for example to adjust the roughness of the surfaces or to obtain micromechanical systems, such as passages for microfluidic systems. Due to its high hardness and chemical resistance, silicon carbide surfaces can only be processed with silicon carbide- or diamond-coated tools, which makes the processes very complex and expensive.

Furthermore, it has not been possible to date to manipulate the surfaces of silicon carbide-containing materials or silicon carbide-containing articles in terms of their chemical properties or chemical composition in a targeted and locally limited manner. Although it is possible, for example in the context of additive manufacturing, to use different precursor materials or mixtures for producing different parts of a silicon carbide-containing article, this method is very costly, since different precursor mixtures have to be used specifically for different parts of the article to be produced. Furthermore, there is as yet no possibility of subsequently modifying the chemical properties of the surface of silicon carbide-containing articles in a locally limited manner.

The state of the art therefore lacks methods for obtaining silicon carbide-containing articles with detailed, highly resolved and, if necessary, structured surfaces quickly and inexpensively by means of additive manufacturing processes. Furthermore, it is also not possible to modify the chemical properties and chemical composition of the surface of silicon carbide-containing articles in a targeted and locally limited manner, at least not at a reasonable cost.

It is thus an object of the present invention to avoid, or at least to mitigate, the previously described disadvantages and problems associated with the prior art.

In particular, it is an object of the present invention to provide a method for producing silicon carbide-containing articles with specific and adjustable surface properties and contours, which method enables shaping of silicon carbide-containing articles on the one hand and specific adjustment of the properties of surfaces of silicon carbide-containing materials on the other hand.

In particular, it is an object of the present invention to provide a method which can be used flexibly and inexpensively and which permits the properties of the surfaces of articles made of silicon carbide-containing materials to be selectively structured or also smoothened.

In addition, a further object of the present invention is to provide a method which enables the chemical properties of silicon carbide-containing materials, in particular of silicon carbide-containing surfaces, to be modified in a locally limited manner by simple means.

Furthermore, it should be noted with respect to all relative or percentage, in particular weight-related, quantitative data mentioned below that these are to be selected by the person skilled in the art within the scope of the present invention in such a way that in total the ingredients, additives or auxiliaries or the like always result in 100% or 100 wt. %. However, this is self-evident for the person skilled in the art.

In addition, it applies that all parameter values or the like mentioned in the following can be determined with standardized or explicitly stated determination methods or determination methods familiar to the skilled person.

With this proviso made, the subject-matter of the present invention will be explained in more detail below.

Subject-matter of the present invention—according to a first aspect of the present invention—is a method for producing and/or modifying silicon carbide-containing articles, wherein a silicon carbide-containing article is produced by means of additive manufacturing, and following or during the additive manufacturing, a surface of the at least partially produced silicon carbide-containing article is processed by ablation or by chemical modification of the surface in that the surface of the article is irradiated, in particular heated, in a site-selective and locally limited manner by means of at least one laser beam.

Within the scope of the present invention, it is thus possible to combine additive manufacturing processes with a method for ablation or chemical modification of silicon carbide-containing materials and to provide a method for producing highly resolved or surface-modified silicon carbide-containing articles.

The method according to the invention thus enables the additive manufacturing of articles made of silicon carbide-containing materials which either comprise very high resolution, i.e. sharp contours or microstructures, or which differ in their chemical modifications or compositions in certain areas.

Such an overall method is not yet known from the prior art.

In particular, the method according to the invention makes it possible to process the surfaces of articles made of silicon carbide-containing materials already during the implementation of a large number of additive manufacturing processes which, for example due to the complex geometry of the manufactured article or component, are no longer available for processing with tools after completion of the silicon carbide-containing article.

Advantageously, in the context of the present invention, a method for ablation and/or chemical modification of surfaces of silicon carbide-containing articles is combined with an additive manufacturing process that equally uses a laser to perform the additive manufacturing.

Ideally, therefore, the same apparatuses can be used for both additive manufacturing and surface processing in the context of the present invention. However, this is only ever possible if the surface of the silicon carbide-containing material is heated for the surface processing, i.e. the surface processing is performed thermally. If, for example, the ablation is carried out with excimer lasers, which emit ultra-short light pulses in the UV range, the ablation is carried out by Coulomb explosion—as will be explained below—and another laser system must be used for the additive manufacturing.

In this context, it is preferably the case that the additive manufacturing is selected from powder bed processes, in particular selective synthetic crystallization, methods based on laser deposition welding or methods based on inkjet printing.

In selective synthetic crystallization (SSC), the production of an article is not carried out from the melt, but from the gas phase. The apparatus set-up and implementation of selective synthetic crystallization corresponds to selective laser melting, i.e. the same apparatus can be used for selective synthetic crystallization under very similar conditions as for selective laser melting. By means of the laser radiation, the energy required to transfer the starting materials into the gas phase can be introduced into a preferably powdery starting material, in particular into a precursor granulate. Usually, the laser beam causes the precursor materials to decompose into gaseous products, which then immediately recombine to form the desired silicon carbide-containing materials and are obtained in crystalline form.

For, as the applicant has surprisingly found out, the surfaces of silicon carbide-containing materials and articles can be easily and readily processed by means of laser radiation, in particular by means of pulsed laser radiation, preferably using a pulsed laser.

On the one hand, by the targeted selection and variation of the irradiated laser energy and the associated locally sharply limited generation of high temperatures on the surface of the silicon carbide-containing material, either diffusion processes can be generated in the surface of the silicon carbide-containing material, so that surfaces enriched with carbon or silicon can be obtained, for example, or the material is removed by ablation, in particular by sublimation, whereby the surface of the silicon carbide-containing article can be structured and geometric shaping of articles made of silicon carbide-containing material is also possible.

Furthermore, in particular through the use of lasers with pulse lengths in the femto- or picosecond range, it is possible to process the surface of silicon carbide-containing materials by ablation with only a small input of thermal energy. In this case, the material is ablated via so-called Coulomb explosions (CE) in the nanoscale range. In the Coulomb explosion, the ultra-short laser pulse usually creates an electron-deficient zone in a small region of only a few nanometers or micrometers on the surface of the silicon carbide-containing material, resulting in a large number of positively charged ions that repel each other. Through the repelling electrical forces, particles in the nanometer range are removed from the surface of the silicon carbide-containing material. The pulse duration or length is typically in the range of 10 fs to 10 ps and the laser intensity is in the range of 1010 to 1013 W/cm2. If by the method the surfaces are to be processed by ablation only, then lasers with pulse lengths in the femto- or picosecond range are preferably used. Particularly preferably, an excimer laser with radiation in the UV range is used for this type of surface treatment.

Through the use of a laser, the silicon carbide-containing material is exposed to the energy effect only very shortly and selectively. In particular, the laser radiation irradiates and processes only an area that corresponds approximately to the width or area of the laser beam. The penetration depth into the silicon carbide-containing material is also only a few nanometers or micrometers. In this way, very site-selective and locally limited processing of the surface is possible, i.e., for example, nano- or microstructures with a depth of only a few nanometers or micrometers can be produced on the surface of the silicon carbide-containing material.

In the context of the present invention, locally selective means that the laser beam or laser radiations can be directed to a defined and fixed site of the silicon carbide-containing material or a substrate. In the context of the present invention, locally limited preferably means that not the entire surface of the silicon carbide-containing material is affected, but only a sharply defined area. In particular, in the context of the present invention, locally limited means an area on the surface of the silicon carbide-containing material that corresponds to the area that is scanned by the laser beam. Preferably, the irradiated or heated area of the silicon carbide-containing material corresponds to the area which is scanned by the laser beam, i.e. the effects of the laser radiation are limited to the directly irradiated material and, if possible, no or only a very slight remote effect occurs.

In the context of the present invention, an article is understood to mean, on the one hand, a three-dimensional structure, in particular a component, or also a coating, i.e. a layer only a few micrometers or millimeters thick. Silicon carbide-containing article preferably means an article containing and/or consisting of silicon carbide-containing material, preferably consisting of silicon carbide-containing material.

A surface of a silicon carbide-containing article in the context of the present invention means the interface of the silicon carbide-containing article, for example, with the surrounding atmosphere or also with other components.

In the context of the present invention, a silicon carbide-containing material means a material that contains or consists of silicon carbide-containing compounds. In the context of the present invention, a silicon carbide-containing compound is to be understood as a binary, ternary or quaternary inorganic compound whose molecular formula contains silicon and carbon. In particular, a silicon carbide-containing compound does not contain molecularly bound carbon, such as carbon monoxide or carbon dioxide; rather, the carbon is present in a solid-state structure.

In the context of the present invention, the silicon carbide-containing material is typically selected from silicon carbide, doped silicon carbide, non-stoichiometric silicon carbide, doped non-stoichiometric silicon carbide, and silicon carbide alloys. The method according to the invention can thus be used to process a wide range of different silicon carbide-containing materials, in particular different silicon carbide compounds.

In the context of the present invention, a non-stoichiometric silicon carbide is understood to be a silicon carbide which does not contain carbon and silicon in the molar ratio 1:1, but in ratios deviating therefrom. Typically, a non-stoichiometric silicon carbide in the context of the present invention comprises a molar excess of silicon.

In the context of the present invention, silicon carbide alloys are understood to be compounds of silicon carbide with metals, such as titanium or also other compounds, such as zirconium carbide or boron nitride, which contain silicon carbide in varying and highly fluctuating proportions. Silicon carbide alloys often form high-performance ceramics, which are characterized by a particular hardness and temperature resistance.

If in the context of the present invention a non-stoichiometric silicon carbide is used, the non-stoichiometric silicon carbide is usually a silicon carbide of the general formula (I)

SiC1-x (I)

with

with x=0.05 to 0.8, in particular 0.07 to 0.5, preferably 0.09 to 0.4, more preferably 0.1 to 0.3.

Such silicon-rich silicon carbides have a particularly high mechanical strength and are suitable for a wide range of applications as ceramics.

If in the context of the present invention the silicon carbide-containing compound is a doped silicon carbide, the silicon carbide is typically doped with an element selected from the group consisting of nitrogen, phosphorus, arsenic, antimony, boron, aluminum, gallium, indium and mixtures thereof. Preferably, the silicon carbide is doped with elements of the 13th and 15th groups of the periodic table of the elements, by which in particular the electrical properties of the silicon carbide can be specifically manipulated and adjusted. Such doped silicon carbides are particularly suitable for applications in semiconductor technology. As already mentioned, the doped silicon carbide can be a stoichiometric silicon carbide or a non-stoichiometric silicon carbide, wherein the doping of stoichiometric silicon carbides is more preferably, since these are increasingly used in semiconductor technology.

If in the context of the present invention a doped silicon carbide is used, it has been well proven if the doped silicon carbide contains the doping element in amounts of 0.000001 to 0.0005 wt. %, in particular 0.000001 to 0.0001 wt. %, preferably 0.000005 to 0.0001 wt. %, more preferably 0.000005 to 0.00005 wt. %, based on the doped silicon carbide. For the specific adjustment of the electrical properties of the silicon carbide, extremely small amounts of doping elements are thus completely sufficient. The above-mentioned amounts of doping elements apply to both stoichiometric and non-stoichiometric silicon carbides.

If in the context of the present invention the silicon carbide-containing compound is a silicon carbide alloy, the silicon carbide alloy is usually selected from MAX phases, alloys of silicon carbide with elements, in particular metals, and alloys of silicon carbide with metal carbides and/or metal nitrides. Such silicon carbide alloys contain silicon carbide in varying and highly fluctuating proportions. In particular, it may be envisaged that silicon carbide forms the main constituent of the alloys. However, it is also possible that the silicon carbide alloy contains silicon carbide only in small amounts.

Typically, the silicon carbide alloy comprises the silicon carbide in amounts of 10 to 95 wt. %, in particular 15 to 90 wt. %, preferably 20 to 80 wt. %, based on the silicon carbide alloy.

In the context of the present invention, a MAX phase means in particular carbides and nitrides crystallizing in hexagonal films of the general formula Mn+1AXn with n=1 to 3. M stands for an early transition metal from the 3rd to 6th group of the periodic table of the elements, while A stands for an element of the 13th to 16th group of the periodic table of the elements. Finally, X is either carbon or nitrogen. In the context of the present invention, however, only those MAX phases are of interest whose molecular formula contains silicon carbide (SiC), i.e. silicon and carbon.

MAX phases comprise unusual combinations of chemical, physical, electrical and mechanical properties, as they exhibit both metallic and ceramic behavior, depending on the conditions. This includes, for example, high electrical and thermal conductivity, high resistance to thermal shock, very high hardness, and low coefficients of thermal expansion.

If the silicon carbide alloy is a MAX phase, it is preferred if the MAX phase is selected from Ti4SiC3 and Ti3SiC.

In particular, the aforementioned MAX phases are highly resistant to chemicals as well as oxidation at high temperatures, in addition to the properties already described.

If the silicon carbide-containing compound is an alloy of silicon carbide, it has been found suitable in case the alloy is an alloy of silicon carbide with metals, if the alloy is selected from alloys of silicon carbide with metals from the group of Al, Ti, V, Cr, Mn, Co, Ni, Zn, Zr and mixtures thereof.

If the alloy of silicon carbide is selected from alloys of silicon carbide with metal carbides and/or nitrides, it has been found suitable if the alloys of silicon carbide with metal carbides and/or nitrides are selected from the group of boron carbides, in particular B4C, chromium carbides, in particular Cr2C3, titanium carbides, in particular TiC, molybdenum carbides, in particular Mo2C, niobium carbides, in particular NbC, tantalum carbides, in particular TaC, vanadium carbides, in particular VC, zirconium carbides, in particular ZrC, tungsten carbides, in particular WC, boron nitride, in particular BN, and mixtures thereof.

In the context of the present invention, it is preferably provided that additive manufacturing is a manufacturing process which is carried out with the aid of laser radiation. The use of additive manufacturing processes involving the production of silicon carbide-containing materials by the use of laser energy or beams has the advantage that, ideally, the same laser used for additive manufacturing can also be used for ablation or chemical modification of the surface of the silicon carbide-containing object. Thus, ideally, the same apparatus design can be used to perform both additive manufacturing and surface processing, which greatly simplifies the performance of the process within the scope of the invention and makes the apparatus design very cost effective. As previously stated, this is not possible if the surface treatment, in particular the ablation, is performed by means of Coulomb explosion, i.e. if an excimer laser is preferably used. In this case, the device for carrying out the process has at least two different lasers and/or the additive manufacturing and surface treatment are carried out with different lasers.

Within the scope of additive manufacturing, the procedure is usually such that a layer of silicon carbide-containing material is selectively deposited on a substrate, so that a layer or film from which the object is constructed is obtained. Subsequently, another layer of silicon carbide-containing material is selectively deposited on the previously obtained layer, so that another layer of the object containing silicon carbide-containing material or consisting of silicon carbide-containing material is obtained. These process steps are repeated until the desired silicon carbide-containing object is finally produced.

In the context of the present invention, it is now possible to carry out process step (b), i.e. the process step of surface processing, subsequent to the additive manufacturing or also during the additive manufacturing, for example after building up one or more layers of the silicon carbide-containing object.

In the context of the present invention, particularly good results are obtained when the silicon carbide-containing material is obtained by decomposition of precursor materials and is deposited onto a surface, in particular a substrate. In this context, it has proven effective if gaseous, liquid or solid precursors containing a carbon source and a silicon source are irradiated, in particular decomposed, by means of a laser beam and the silicon carbide-containing material is deposited on a surface, in particular a substrate.

In the context of the present invention, additive manufacturing may be selected from all suitable processes. However, particularly good results are obtained when the additive manufacturing is selected from selective synthetic crystallization, printing methods with subsequent laser irradiation, and laser deposition welding, as well as methods based on these methods.

In the context of the present invention, it has proven particularly well if the additive manufacturing is selected from powder bed processes, in particular selective synthetic crystallization, methods based on laser deposition welding or methods based on inkjet printing.

Selective synthetic crystallization is described, for example, in DE 10 2017 110 362 A1. Here, powdery precursor materials are converted into silicon carbide-containing materials by irradiation with a laser beam.

A suitable inkjet method is described in DE 10 2017 110 361 A1. In the method disclosed in DE 10 2017 110 361 A1, liquid precursor materials are applied to a substrate surface by means of an inkjet printing process and are then converted into the corresponding silicon carbide-containing materials by exposure to laser radiation.

In addition, it is also possible to process solid, liquid or gaseous precursor materials into silicon carbide-containing articles using a method similar to laser deposition welding. In this process, a particle beam of solid, liquid or gaseous particles is directed onto a substrate surface and irradiated by a laser beam at or before impingement on the substrate surface so that the precursor compounds are decomposed and selectively converted to silicon carbide.

In the context of the present invention, it is customary to proceed in such a way that prior to producing the silicon carbide-containing article, a digital image, a so-called digital twin of the article is created. The creation of a digital image of the article to be manufactured makes it possible, in particular, to create a digital model of the article to be manufactured with virtually any resolution and accuracy, with the aid of which the manufacturing can subsequently be carried out, in particular by means of additive and subtractive manufacturing or by means of additive manufacturing and chemical modification.

In the context of the present invention, it is usually envisaged that the digital image is created by means of geometric modeling, in particular by means of CAD. CAD (Computer Aided Design) is usually understood to mean the computer-aided creation and modification of models. With the aid of CAD, for example, it is also possible to calculate the arrangement and size of the individual layers required to create an article, in particular a three-dimensional article or component.

In the context of the present invention, it is usually provided that the silicon carbide-containing article is produced by alignment with the digital image. In this context, in particular by the combination of additive and subtractive manufacturing, if necessary in combination with a chemical modification of the surface, a highly resolved silicon carbide-containing article is created which is as accurate and rich in contrast as possible.

In this context, it may be envisaged that the digital image deviates to a predetermined extent from the article to be manufactured due to special features in the manufacturing process, such as thermal conditions. Thus, in the context of additive manufacturing as well as subsequent surface treatment, size fluctuations or distortion caused by heating and cooling of the silicon carbide-containing article or the partially finished silicon carbide-containing article must always be considered. This applies in particular to silicon carbide-containing articles made of silicon carbide or doped silicon carbide and, to a much lesser extent, to articles made of silicon carbide alloys, since these comprise only a small thermal expansion.

The method according to the invention also allows, for example, by modifying the surface of individual layers of the silicon carbide-containing object applied during additive manufacturing, the chemical properties and subsequently also the electrical properties of silicon carbide-containing materials in the interior of an article containing or consisting of silicon carbide-containing materials to be specifically adjusted. For example, conductive paths for conducting electrical currents can be selectively created inside an article made of silicon carbide-containing material.

According to a preferred embodiment of the present invention, it is provided that the silicon carbide-containing article is measured during and/or after additive manufacturing. By measuring the article, in particular by measuring the article with a laser, it is in particular possible to precisely monitor the respective manufacturing progress. It is particularly preferred in this context if the additive manufacturing is carried out by means of a laser and if the laser, which is used for the additive manufacturing, is also used at the same time for measuring the manufactured article. This can be done, for example, by using an interferometer.

Particularly good results are obtained in this context if the article is measured during and/or after additive manufacturing and if the surface of the article is processed after comparison with the digital image so that the article and the digital image match or deviate from each other to a predetermined extent. In this context, it may further be provided that the surface of the article is processed during or after additive manufacturing. This means that the article containing silicon carbide, which has not yet been completely manufactured, can also be irradiated with laser radiation and processed by means of ablation or chemical modification before additive manufacturing is completed.

As previously stated, it may be customary in the context of the present invention to heat the surface of the silicon carbide-containing material. If the surface of the silicon carbide-containing article is heated by means of the laser beam, it has been well proven if the surface of the silicon carbide-containing article is heated to temperatures in the range of 500 to 3,500° C., in particular 600 to 3,200° C., preferably 700 to 3,000° C. At temperatures in the aforementioned range, either chemical modifications of the silicon carbide-containing material of the article or structural processing by ablation can be carried out.

According to a preferred embodiment of the present invention, the surface of the silicon carbide-containing article is processed by means of ablation. This means that the surface of the silicon carbide-containing article is processed by means of subtractive manufacturing, i.e. with material removal.

In this context, it may in particular be provided that by means of ablation the surface of the silicon carbide-containing article is structured and/or smoothened, in particular microstructured and/or smoothened, or that the silicon carbide-containing article is processed geometrically.

Structuring of the surface of the silicon carbide-containing article means in particular that defined and specified structures, preferably in the nanometer or micrometer range, i.e. so-called microstructures, are created on the surface of the silicon carbide-containing material, for example in order to adjust the surface roughness of the silicon carbide-containing material or to provide structures for micromechanical systems.

Equally, however, it is also possible for the surface to be smoothened, for example following additive manufacturing. The layered structure of the article produced as a result of additive manufacturing can often still be seen, particularly at the interfaces of the article. In these cases, surface processing, in particular smoothing, can significantly improve the surface quality; ideally, it is after the surface processing no longer recognizable that the article was built up by means of additive manufacturing. In addition, however, it is also possible to geometrically process the silicon carbide-containing article. During geometric processing, at least parts of the silicon carbide-containing article are subjected to shaping by ablation, in particular by the action of laser radiation. In this process, repeated or continuous exposure to the laser radiation can result in material removal in the micrometer to millimeter range or even in the centimeter range. Ablation is therefore suitable, for example, for removing support structures used in additive manufacturing. By precisely adjusting the laser power in combination with an adapted residence time of the laser beam on a partial area of the surface of the silicon carbide-containing article, elevations can be flattened in a targeted manner, for example, since the elevations heat up more quickly and material is removed there before depressions, which remain cooler due to better heat conduction, deepen.

Furthermore, ablation by means of laser radiation, due to the possibility of producing structures reproducibly and with high precision in the nanometer or micrometer range, combined with the high strength of silicon carbide and silicon carbide-containing materials, opens up new possibilities for microstructured silicon carbide-containing surfaces.

In particular, it is possible, for example, to selectively adjust the roughness of the surface of the silicon carbide-containing article for mechanical applications. Similarly, surfaces of silicon carbide-containing articles can be selectively structured for micromechanical applications. Furthermore, the electrical and physical properties of electrodes and membranes can be influenced by targeted structuring, and in particular the electrochemical properties can also be specifically adjusted.

Furthermore, the structuring of the surfaces of silicon carbide-containing articles can also be used in the field of semiconductor technology: For example, structuring of semiconductor layers with different functions can be carried out. Similarly, it is also possible to obtain complex three-dimensional structures by successively applying a number of two-dimensionally structured materials, wherein a first layer is first produced, in particular by means of additive manufacturing, and then structured by ablation under the action of laser radiation, whereupon a second layer is applied by means of additive manufacturing and likewise is structured.

In addition, it is also possible to geometrically process surfaces of silicon carbide-containing articles, in particular, for example, the surfaces of silicon carbide-containing moldings. This includes, in particular, the removal of support structures from additive manufacturing or the targeted application of holes, a re-sharpening of edges or a precise reworking of a silicon carbide-containing article produced in rapid printing processes and low resolution by means of additive manufacturing.

During ablation, the surface of the silicon carbide-containing article to be processed is usually precisely measured. In particular, it is convenient to use the laser to be used for surface processing, in particular ablation, also for measuring the surface of the silicon carbide-containing article; in this case, for example, either alternating processing or scanning passes of the surface can be performed with the laser, or a real-time measurement of the surface of the silicon carbide-containing article can be performed. Preferably, a real-time measurement of the currently processed part of the surface is performed; in particular, a measurement of the processed surface segment is possible by measuring the reflected laser beam via an interferometer. By comparison with a digital image, in particular a digital twin, real-time control of both the irradiation location of the laser radiation and the laser power can then be performed in order to achieve the desired material removal in a targeted manner.

If in the context of the present invention, the surface of the silicon carbide-containing article is processed by means of ablation, it has been well proven if the surface of the silicon carbide-containing article is heated to temperatures above 2,200° C., in particular above 2,500° C., preferably above 2,700° C., more preferably above 2,900° C. At the aforementioned temperatures, sublimation of silicon carbide-containing materials is usually possible.

Similarly, it may be provided that the surface of the silicon carbide-containing article is heated to temperatures in the range from 2,200 to 3,500° C., in particular from 2,500 to 3,300° C., preferably from 2,700 to 3,200° C., more preferably from 2,900 to 3,000° C.

In addition, as previously stated, ablation, i.e. material removal, of the silicon carbide-containing material is also possible without significant heating of the silicon carbide-containing material in that pulse lasers with pulse lengths in the range of 10 ps or less are used. Typically, the pulse lasers used for this case have pulse lengths in the range of 1 fs to 10 ps, in particular 10 fs to 10 ps, preferably 10 fs to 2 ps, more preferably 10 fs to 100 fs. By using pulse lasers with such short pulse lengths, the material is removed by Coulomb explosion, so that only a small amount of thermal energy is introduced into the silicon carbide-containing material.

As previously stated, the laser radiation can also be used to chemically modify the surface of the silicon carbide-containing article. Typically, the chemical modification of the surface is thereby selected from the group consisting of an enrichment of silicon on the surface of the silicon carbide-containing material, an enrichment of carbon on the surface of the silicon carbide-containing material, production of graphene and/or graphite on the surface of the silicon carbide-containing material, production of silica on the surface of the silicon carbide-containing material, and combinations thereof.

Typically, in the context of the present invention, the temperatures for chemical modification of the surface of the silicon carbide-containing material are not selected as high as for ablation of the silicon carbide-containing article. The temperature increase triggers diffusion processes in the immediate proximity of the surface, which lead, for example, to an accumulation of silicon or of carbon and then finally to the production of carbon, in particular to the production of graphene and/or graphite, on the surface of the silicon carbide-containing article. Similarly, the production of thin silicon oxide layers is also possible if the heating of the surface is carried out in the presence of small amounts of oxygen.

By chemically modifying the surface of the silicon carbide-containing article, it is possible to change the properties, in particular the electrical properties, of the silicon carbide-containing material in a targeted, site-selective and locally limited manner. This is of particular interest in the field of semiconductor applications, especially by combining it with an additive method for applying further films or layers of the silicon carbide-containing article, since the individual layers of the article can then be specifically manipulated in their electrical properties at their respective surfaces during additive manufacturing.

If, in the context of the present invention, chemical modification of the surface of the silicon carbide-containing article is carried out by means of laser radiation, the surface of the silicon carbide-containing material is usually heated to temperatures above 500° C., in particular above 600° C., preferably above 700° C., more preferably above 750° C.

Similarly, it may be provided that the surface of the silicon carbide-containing article is heated to temperatures in the range from 500 to 2,000° C., in particular from 600 to 1,800° C., preferably from 700 to 1,600° C., more preferably from 750 to 1,500° C. Chemical modification on the surface of the silicon carbide-containing article usually occurs only to a depth of a few micrometers or nanometers, in particular less than 1 μm, preferably less than 100 nm. Thus, below 800° C., diffusion of silicon to the surface of the silicon carbide-containing article begins, and above 800° C., silicon desorption from the surface of the silicon carbide-containing articles occurs. At temperatures above 1,200° C., rapid desorption of silicon from the silicon carbide-containing surface occurs and formation of graphene begins. Graphene formation follows successively, in that graphene layer is formed one graphene layer at a time, wherein, before a new graphene layer is formed, a carbon-rich silicon carbide is first formed from a layer of the silicon carbide-containing material, which is finally converted into graphene by further desorption of silicon. The graphene formation progresses from the surface of the article into deeper and deeper layers of the silicon carbide-containing article.

If the heating of the surface of the silicon carbide-containing article is carried out in the presence of oxygen, silicon dioxide is formed on the surface of the silicon carbide-containing material. The silicon dioxide layer is very thin and amounts to only a few lattice constants and its growth is limited. The silicon dioxide surface layer serves as a protective layer for the underlying silicon carbide-containing material and prevents the silicon carbide from decomposing.

To produce carbon-rich silicon carbides, in particular graphene layers on silicon carbide, the method, in particular process step (b), is preferably carried out in a vacuum, more preferably in an ultrahigh vacuum.

According to a particular embodiment of the present invention, by chemical modification of the surface of the silicon carbide-containing article, in particular by enrichment of silicon or carbon on the surface of the silicon carbide-containing material of the silicon carbide-containing article, the surface of the silicon carbide-containing material is activated for doping, in particular for treatment with doping reagents.

By enriching the surface of the silicon carbide-containing material with silicon or carbon, defective structures or defects can be created in the structure of the silicon carbide-containing material of the silicon carbide-containing article, into which the corresponding doping elements, in particular elements of the 3rd and 5th main groups of the periodic table of the elements, can then be introduced. The doping elements can be applied to the surface of the silicon carbide-containing article, for example, either via the gas phase or by treating the surface of the silicon carbide-containing material, in particular the activated surface, with liquids, in particular with solutions or dispersions containing compounds of the doping elements.

The conversion to the correspondingly doped silicon carbide-containing materials can be carried out either by annealing the silicon carbide-containing article at elevated temperatures, in particular at temperatures above 1,300° C., or by irradiation with a laser beam.

If a solution or a dispersion is used which comprises at least one doping reagent, the solution or dispersion typically comprises the doping reagent in amounts of 0.000001 to 0.5 wt. %, preferably 0.000005 to 1 wt. %, more preferably 0.000001 to 0.1 wt. %, based on the solution of the dispersion.

As to the chemical nature of the doping reagent, the reagent usually contains at least one doping element. Preferably, the doping element is selected from elements of the 3rd and 5th main groups of the periodic table. More preferably, the doping reagent is selected from compounds of an element of the 3rd or 5th main group of the periodic table of elements, which is soluble or finely dispersible in a solvent or dispersant. The doping reagent is usually selected from nitric acid, ammonium chloride, melamine, phosphoric acid, phosphonic acids, boric acid, borates, boron chloride, indium chloride and mixtures thereof.

If doping with nitrogen is intended, the solution may contain nitric acid, ammonium chloride or melanin. If doping with phosphorus is envisaged, phosphoric acid or phosphates or phosphonic acids can be used, for example. In addition, nitrogen doping is also possible by carrying out the method according to the invention in a nitrogen atmosphere.

If doping with boron is intended, boric acids, borates or boron salts, such as boron trichloride, are used, for example.

If doping with indium is envisioned, water-soluble indium salts, such as indium chloride, are typically used as the doping reagent.

As previously explained, with the method according to the invention, very sharp contours can be displayed, in particular a very sharply limited input of energy is possible. The sharpness of the contours is limited almost exclusively by the resolution, i.e. the width or area of the laser beam. In the context of the present invention, laser beams with a resolution of 0.1 to 150 μm, in particular 1 to 100 μm, preferably 10 to 50 μm, are usually used.

Furthermore, the method is usually not carried out in a standard atmosphere. In the context of the present invention, it has been well proven if the method is carried out in an atmosphere containing no more than 5 vol. % oxygen or in a vacuum. Particularly good results are obtained in this context if the atmosphere in which the method is carried out contains at most 3 vol. %, in particular at most 2 vol. %, preferably at most 1 vol. % of oxygen, preferably at most 0.5 vol. % of oxygen.

Furthermore, it may be provided that the atmosphere in which the method is carried out contains 0 to 5 vol. % of oxygen, in particular 0.01 to 3 vol. % of oxygen, preferably 0.05 to 2 vol. % of oxygen, more preferably 0.08 to 1 vol. % of oxygen, most preferably 0.1 to 0.5 vol. % of oxygen.

Preferably, the method according to the invention is carried out in an oxygen-free atmosphere or in a vacuum, in particular in a high vacuum. Small amounts of oxygen are used in the process atmosphere only if a selective oxidation of silicon to silicon dioxide and an oxidation of carbon to carbon dioxide in the topmost layer of the silicon carbide-containing material or the silicon carbide-containing article are to take place.

However, it has been particularly well proven in the context of the present invention if the method is carried out at least in part in an inert gas atmosphere, an atmosphere containing doping reagents, or in a vacuum. Particularly preferably, the method according to the present invention is carried out in an inert gas atmosphere or in a vacuum. In the context of the present invention, an inert gas is to be understood as a gas which does not react with the silicon carbide-containing material under process conditions and is also not incorporated therein.

A particularly preferred inert gas in the context of the present invention is argon. In addition, a region-wise doping of silicon carbide-containing materials can be achieved if the atmosphere in which the method according to the present invention is carried out contains doping elements or doping reagents, such as elemental nitrogen. Furthermore, it is equally possible to use also highly volatile organyls or hydrides of compounds of the 3rd and 5th main groups of the periodic table of the elements, which in particular pass into the gas phase under reduced pressure and can be used as doping reagents.

Furthermore, in the context of the present invention, it is usually provided that the laser beams for surface processing are generated by means of a pulse laser. If the laser beams are generated by means of a pulse laser which comprises a pulse length of more than 10 ps, in particular in the nanosecond range, heating of the surface of the silicon carbide-containing article occurs primarily. Via a targeted and locally limited heating of the surface of the silicon carbide-containing article, in particular the chemical modification or ablation of the silicon carbide-containing material can be specifically controlled.

Furthermore, as previously mentioned, it is also possible within the scope of the present invention for the laser beams to be generated by an ultrashort pulse laser. In particular, an ultrashort pulse laser with pulse lengths of 1 fs to 10 ps, in particular 10 fs to 2 ps, preferably 10 fs to 100 fs, can be used for ablation. The use of such ultrashort pulse lasers, in particular with radiation in the UV range, enables ablation of the surface of materials or articles containing silicon carbide with virtually no heating.

In the context of the present invention, it may be envisaged that the laser radiation, in particular for carrying out additive manufacturing and/or for heating the surface of the silicon carbide-containing article, comprises a wavelength in the visible range or in the IR range. If the surface of the silicon carbide-containing article is thermally processed, laser radiation in the visible or IR range can often be used, and in particular the same laser can be used for additive manufacturing and surface processing.

Furthermore, it is equally possible within the scope of the present invention that the laser radiation, in particular for carrying out the ablation, comprises a wavelength in the UV range. This embodiment of the present invention is used in particular when excimer lasers are used, wherein different lasers are preferably used here for the additive manufacturing and the surface processing of the silicon carbide-containing article.

In the context of the present invention, it is furthermore usually provided that the method progress, in particular the ablation, is monitored, in particular continuously monitored.

This is done in particular by in situ-measurement of the surface of the silicon carbide-containing article, in particular by reflection of the laser beam used for processing the surface and/or the laser beam used in additive manufacturing, preferably by evaluation using an interferometer. By comparing the structure of the silicon carbide-containing material just processed with a virtual model, in particular a digital image or digital twin, the method progress can be monitored and the laser power adjusted, in particular during ablation.

Whereas the problem with the use of silicon carbide is that it sublimates and cannot be melted under normal conditions, it has been shown that by using suitable precursor materials which comprise a carbon source and a silicon source, silicon carbide-containing materials, in particular in the form of layers, can be deposited on substrate surfaces by site-selective decomposition of the precursor materials from the gas phase. The layer of silicon carbide-containing material can cover the substrate surface completely or only in certain areas. In the case of repeated application of layers of silicon carbide-containing material, in the context of the present invention a layer of silicon carbide-containing material which has already been completed is assigned to the substrate, wherein its surface then configures the substrate surface at the points at which it covers a substrate material. In the context of the present invention, the substrate may comprise virtually any three-dimensional structure.

In this context, repeated and site-selective application can be used to selectively coat articles as well as to create three-dimensional articles made of silicon carbide-containing materials. In addition, it is also possible not only to coat articles or components, but also to join them using materials containing silicon carbide or to repair damage in the form of material defects.

As previously explained, additive manufacturing is preferably carried out in the form of selective synthetic crystallization, printing processes with subsequent laser radiation, laser deposition welding or processes based on these.

The method based on laser deposition welding is usually a method for depositing silicon carbide-containing materials on a substrate surface, wherein a gaseous, liquid or powdery precursor material containing a silicon source and a carbon source is gasified and/or decomposed by exposure to laser radiation and at least a part of the decomposition products is site-selectively deposited on the substrate surface as silicon carbide-containing material.

This additive method permits the generation of highly resolved and detailed three-dimensional structures, i.e. the course of contours, such as corners or edges, is highly precise and in particular free of burrs.

In particular, this additive method allows very fast and low-cost producing of three-dimensional silicon carbide-containing articles or layers and, in particular, does not require the use of pressure to provide compact non-porous or low-porous materials and materials.

This additive method can be used both to apply coatings of silicon carbide-containing materials to a substrate surface and to build up three-dimensional articles of silicon carbide-containing materials. Similarly, it is also possible to join components by applying silicon carbide-containing materials or to supplement material defects in components.

In the context of carrying out additive manufacturing in the form of a method similar to laser deposition melting, it has been well proven if the precursor material, in particular the powdery precursor material, in finely distributed and directed form, in particular in the form of at least one particle beam, is moved in the direction of the substrate and is gasified and decomposed by action of energy, in particular laser radiation, before or upon impact on the substrate, or that the gaseous decomposition products are moved in the direction of the substrate, in particular in the form of a particle beam.

A particle beam is understood to be a directed stream of particles or particulates with a preferably constant cross-section, which preferably travels linearly. In the context of the present invention, the precursor materials or the decomposition products can be moved in one or more particle beams in the direction of the substrate surface and meet, for example, in a focal point, e.g. the light beam of a laser, or on the substrate surface. The particle beam or beams is or are preferably directed towards the substrate surface.

Within the scope of this embodiment, it is thus possible for the starting compounds to be moved in finely distributed form, preferably in the form of a finely distributed powder, in particular a powder beam, in the direction of the substrate surface and to be gasified and decomposed by the action of energy, in particular by the action of a laser beam, before, in particular immediately before, or upon impacting the substrate surface. In this way, the decomposition products are generated in the immediate proximity of the surface to which they are applied and can be deposited on the cooler substrate surface in preferably single-crystal form. Alternatively, it is also possible for the decomposition products to be moved toward and applied to the substrate surface, for example through a nozzle, wherein the decomposition products deposit at least in part on the substrate surface as the desired silicon carbide-containing material. Here, however, there is always the risk that larger agglomerates will already form in the gas phase and a less dense and homogeneous surface will be obtained.

According to this embodiment, it is more preferred if the precursor material, in particular the powdery precursor material, or the gaseous decomposition products is or are moved in the direction of the substrate by means of at least one nozzle. By using a nozzle, it is in particular possible to obtain a sharply defined particle jet, preferably of gaseous particles or of powder particles, which are applied site-selectively to the substrate surface. Particularly preferably, the nozzle is a powder nozzle or a gas nozzle.

The nozzle can be arranged either coaxially to a laser beam, for example, or laterally. In the coaxial arrangement, the laser beam and nozzle are usually located in a processing head or an assembly, wherein the laser beam is directed almost perpendicularly to the substrate surface and the particle beam intersects it or several particle beams intersect the axis of the laser beam at a focal point. In the lateral arrangement, the laser beam is also typically arranged and movable perpendicular to the substrate surface, wherein a particle beam is sprayed laterally into the axis of the laser beam.

As previously stated, according to this embodiment, the use of powdery precursor materials is more preferably, wherein gaseous or liquid precursor materials may also be used.

Within the scope of this embodiment, it is usually provided that the powdery precursor material is moved in the direction of the substrate in the form of a powder beam, or that the liquid precursor material is moved in atomized form or as a liquid jet in the direction of the substrate, but preferably always in the form of a particle jet. Furthermore, it is possible that the gaseous precursor material is moved towards the substrate in the form of a gas stream. Alternatively, it is also possible that the gaseous decomposition products are moved towards the substrate in the form of a gas jet.

In accordance with this embodiment of the present invention, the additive manufacturing is laser deposition welding or a method similar to laser deposition welding in which the precursor materials are gasified and/or decomposed prior to or until contact with the substrate surface.

In the context of this embodiment of the present invention, it is preferred if the precursor material, in particular the powdery precursor material, is gasified and decomposed in the proximity of the substrate surface by means of laser radiation, in particular in the immediate proximity of the substrate surface. In this way, side reactions and undesired agglomerations are in particular prevented. In the context of the present invention, moreover, the substrate is heated only extremely slightly by the energy introduced, in particular by the laser beam, so that, on the one hand, it is possible to apply the silicon carbide-containing material as stress-free as possible.

Common to all the above-mentioned preferred additive manufacturing processes is that they start from precursor compounds which comprise a carbon source and a silicon source.

In the context of the present invention, a silicon source or a carbon source means compounds which, under process conditions, can release silicon or carbon in such a way that silicon carbide-containing compounds are formed. In this context, silicon and carbon need not be released in elemental form, but it is sufficient if they react under process conditions to form silicon carbide-containing compounds.

The silicon source, the carbon source or also the precursors for any doping or alloying elements can either be specific chemical compounds or, for example, their reaction products, in particular hydrolysates, as will be explained below.

In the context of the present invention, a substrate is to be understood as the material to which the—in particular gaseous—decomposition products of the precursor material are applied. In particular, a substrate in the context of the present invention is a three-dimensional or also an almost two-dimensional formation with a surface on which the decomposition products of the precursor material are deposited as silicon carbide-containing material. The substrate surface can be flat or contoured, in particular with a three-dimensional structure. The substrate can comprise almost any three-dimensional shape. The substrate can thus be a carrier material on which silicon carbide-containing material is deposited layer by layer. The term substrate also includes, in particular, substrate materials which are partially coated with one or more layers of silicon carbide-containing materials. However, a substrate may also be a three-dimensional article joined to a second substrate, in particular another three-dimensional article, by deposited silicon carbide-containing material. In polymer bed processes, the precursor material is first applied to a substrate and then decomposed in a site-selective manner. In printing processes, liquid precursors are also applied to a substrate surface, but in a site-selective manner, and decomposed.

Now, with respect to the substrate onto which the precursor material or its decomposition products are applied, this can be selected from a variety of suitable materials. In the context of the present invention, it is possible that the substrate is selected from crystalline and amorphous substrates. According to a more preferred embodiment of the present invention, the substrate is an amorphous substrate. Particularly good results are obtained if the material is selected from carbon, in particular graphite, and ceramic materials, in particular silicon carbide, silicon dioxide, aluminum oxide, and metals and mixtures thereof. If the method for producing articles of silicon carbide-containing materials according to the present invention is used, the substrate often comprises a plurality of materials, in particular a substrate material and the three-dimensional article of silicon carbide-containing material at least partially built thereon.

In the context of the present invention, the precursor material used for additive manufacturing is preferably selected from gaseous, liquid or powdery precursor materials. The liquid precursor material may be a homogeneous solution or also a dispersion, in particular also a solid-in-liquid dispersion.

In the context of the present invention, a precursor material is to be understood as a chemical compound or a mixture of chemical compounds which react under process conditions to form the desired product materials, in particular silicon carbide-containing materials.

The reaction to the target compounds can take place in a wide variety of ways. Advantageously, however, it is envisaged that the peacursor compounds are cleaved or decomposed under the action of energy, in particular under the action of a laser beam, and pass into the gas phase as reactive particles. Since in the gas phase, due to the special composition of the precursor, silicon and carbon and, if necessary, doping or alloying elements are present in the immediate proximity, the silicon carbide which sublimates only above 2,300° C. or the doped silicon carbide or silicon carbide alloy precipitates. In particular, crystalline silicon carbide absorbs laser energy much less effectively than the precursor materials and conducts heat very well, so that strictly localized deposition of the defined silicon carbide compounds takes place. On the other hand, undesirable components of the precursor compound preferably form stable gases, such as CO2, HCl, H2O, etc., and can be removed via the gas phase.

In the context of the present invention, it may be provided that the precursor material is a solid precursor material, in particular a precursor granulate. Particularly good results are obtained if the precursor granulate is not a powder mixture, in particular not a mixture of different precursor powders and/or granulates. Preferably, when additive manufacturing is carried out as a powder bed process or as laser deposition welding, a homogeneous granulate, in particular a precursor granulate, is used as the precursor material for the method according to the invention.

In this way, by means of short exposure times to energy, in particular laser radiation, the precursor material can pass into the gas phase or the precursor compounds can react to form the desired target compounds, wherein it is not necessary to sublimate individual particles of different inorganic substances with particle sizes in the μm range, the constituents of which must then diffuse to form the corresponding compounds and alloys. Due to the homogeneous precursor granulate preferably used in the present invention or in liquid and gaseous precursors, the individual building blocks, in particular elements, of the silicon carbide-containing target compound are homogeneously distributed and arranged in close proximity to one another, i.e. less energy is required for producing the silicon carbide-containing compounds. This has the advantage that a multilayer structure of silicon carbide-containing material can be built without heating the top layer of the silicon carbide-containing material forming the substrate surface to temperatures at which silicon carbide sublimes.

If a precursor granulate is used, the precursor granulate is usually obtainable from a precursor solution or a precursor dispersion, in particular a precursor sol. In the context of the present invention, the precursor granulate is thus preferably obtained in finely divided form from a liquid, in particular from a solution or dispersion. In this way, a homogeneous distribution of the individual components, in particular precursor compounds, can be achieved in the granules, wherein preferably the stoichiometry of the silicon carbide-containing material to be produced is already preformed. For printing processes, in particular ink-jet processes, the precursor solution or dispersion, in particular the precursor sol, can be used directly.

If the precursor granulate is obtainable from a solution or dispersion, in particular a gel, the precursor granulate is obtained by drying the precursor solutions or dispersions or the resulting gel.

As far as the particle sizes of the precursor granulate are concerned, these can vary within wide ranges depending on the respective chemical compositions, the laser energy used and the properties of the material or article to be produced. In general, however, the precursor granulate comprises particle sizes in the range from 0.1 to 150 μm, in particular 0.5 to 100 μm, preferably 1 to 100 μm, more preferably 7 to 70 μm, most preferably 20 to 40 μm.

Particularly good results are obtained if the particles of the precursor granulate comprise a D60 value in the range of 1 to 100 μm, in particular 2 to 70 μm, preferably 10 to 50 μm, more preferably 21 to 35 μm. The D60 value for the particle size represents the limit below which the particle size of 60% of the particles of the precursor granulate lies, i.e. 60% of the particles of the precursor granulate comprise particle sizes which are smaller than the D60 value.

In this context, it may equally be provided that the precursor granules comprise a bimodal particle size distribution. In this way, precursor granulates with a high bulk density are in particular accessible.

Now, with regard to the temperatures at which precursor material is gasified and/or decomposed in additive manufacturing, it has proven useful if the precursor material, in particular the precursor granulate or a precursor sol, is heated by the action of energy, in particular at least in some areas, to temperatures in the range from 1,600 to 2,100° C., in particular 1,700 to 2,000° C., preferably 1,700 to 1,900° C. At the aforementioned temperatures, all components of the precursor material pass into the gas phase and the precursor materials are decomposed to the desired reactive species, which then react to form the target compounds.

As previously stated, the use of solid, in particular powdery, or liquid precursor materials is preferred. However, additive manufacturing can also be carried out with gaseous precursor materials, in particular in methods similar to laser deposition welding.

If gaseous precursor materials are used in additive manufacturing, the precursor materials are decomposed by the action of energy and at least some of the decomposed precursor materials are site-selectively deposited on the substrate surface as silicon carbide-containing material.

In the context of the present invention, as previously stated, it is customary for the silicon carbide-containing material to be selected from optionally doped silicon carbide, optionally doped non-stoichiometric silicon carbide, silicon carbide alloys and mixtures thereof. The production of silicon carbide, in particular doped stoichiometric silicon carbide from precursor compounds, in particular powdery precursor compounds, is known in principle and is practiced, for example, within the scope of German patent application 10 2015 105 085.4.

Suitable precursor materials are described in more detail below.

In the context of the present invention, for example, it may be envisaged that precursor materials are used which are either mixtures of liquid and/or gaseous carbon and silicon sources, i.e. compounds which release carbon or silicon or reactive intermediates under reaction conditions, or liquid solutions or dispersions which comprise the carbon and silicon sources.

If in the context of the present invention liquid and/or gaseous carbon sources are used as precursor materials, it may be provided that the liquid and/or gaseous carbon source is selected from alkanes, amines, alkyl halides, aldehydes, ketones, carboxylic acids, amides, carboxylic acid esters and mixtures thereof, in particular C1- to C8-alkanes, primary and secondary C1- to C4-alkylamines, C1- to C8-alkyl halides, C1- to C8-aldehydes, C1- to C8-ketones, C1- to C8-carboxylic acids, C1- to C8-amides, C1- to C8-carboxylic acid esters and mixtures thereof.

Particularly good results are obtained in this context if the gaseous and/or liquid carbon source is selected from C1- to C8-alkanes, in particular C1- to C4-alkanes, and mixtures thereof. In the context of the present invention, it is thus preferred if the gaseous or liquid carbon source is a short-chain and thus highly volatile alkane. In particular, when oxygen-containing functional groups are used, care must be taken to ensure that the excess of carbon is so high that carbon is always oxidized to carbon monoxide or carbon dioxide and that silicon is not oxidized to silicon dioxide or that silicon dioxide is immediately reduced again by carbon, since silicon dioxide would significantly disrupt the structure and function of the silicon carbide-containing fibers or foams.

Furthermore, it has been well proven if the liquid and/or gaseous silicon source is selected from silanes, siloxanes and mixtures thereof, preferably silanes.

If siloxanes are used as precursors, it is possible, if suitable siloxanes are selected, for the siloxane or siloxanes to represent both the carbon source and the silicon source and no further precursors need to be used with the exception of any doping or alloying reagents.

Preferably, however, solid, in particular powdery, precursor materials are used. The solid precursor materials are usually in the form of precursor granules containing at least one silicon source, at least one carbon source and optionally precursors for doping and/or alloying elements.

In the case of precursor granules, the silicon source is usually selected from silane hydrolysates and silicic acids and mixtures thereof. In the context of the present invention, the silicon source, i.e. the precursor of the silicon in the silicon carbide-containing compound, is obtained in particular by hydrolysis of tetraalkoxysilanes, whereby in the precursor granules the silicon is preferably present in the form of silicic acid or silane hydrolysates.

Now, as far as the carbon source in the precursor granules is concerned, this is usually selected from the group of sugars, in particular sucrose, glucose, fructose, invert sugar, maltose; starch; starch derivatives and organic polymers, in particular phenol-formaldehyde resin, resorcinol-formaldehyde resin, and mixtures thereof and/or reaction product thereof, in particular sugars and/or reaction products thereof. Particularly preferably, the carbon source is selected from sugars and their reaction products, wherein sucrose and/or invert sugar and/or their reaction products are preferably used. Also, in the case of the carbon source, not only the actual reagent but also its reaction product can be used.

If the precursor granules are used to prepare a (stoichiometric) silicon carbide, the composition typically contains the silicon source in amounts of 40 to 60 wt. %, preferably 45 to 55 wt. %, based on the composition, the carbon source in amounts of 40 to 60 wt. %, preferably 45 to 55 wt. %, based on the composition, and optionally precursors of doping elements.

The precursors for the doping elements are usually contained in the precursor granules only in very small amounts, in particular in the ppm range.

If a non-stoichiometric silicon carbide is produced with the precursor granules, the composition usually comprises the silicon source in amounts of 60 to 90 wt. %, in particular 65 to 85 wt. %, preferably 70 to 80 wt. %, based on the composition, the carbon source in amounts of 10 to 40 wt. %, in particular 15 to 35 wt. %, preferably 20 to 30 wt. %, based on the composition, and optionally precursors for doping elements.

With precursor granules which comprise the carbon source and the silicon source in the above-mentioned quantity ranges, non-stoichiometric silicon carbides with an excess of silicon can be produced in an outstandingly reproducible manner.

If the precursor granules are used for producing a silicon carbide alloy, the composition typically includes.

the silicon source in amounts of 5 to 40 wt. %, in particular 5 to 30 wt. %, preferably 10 to 20 wt. %, the carbon source in amounts of 10 to 60 wt. %, in particular 15 to 50 wt. %, preferably 20 to 50 wt. %, and one or more precursors for alloying elements in amounts of 5 to 70 wt. %, in particular 5 to 65 wt. %, preferably 10 to 60 wt. %, in each case based on the composition.

A more preferably used precursor granulate is obtainable from a precursor solution or a precursor dispersion. In this context, it is particularly preferred if the precursor granulate is obtainable by a sol-gel method or by drying a sol. In sol-gel methods, usually solutions or finely divided solid-in-liquid dispersions are produced, which are converted by subsequent aging and the thereby occurring condensation processes to a gel, which contains larger solid particles.

After drying the gel or the sol, a particularly homogeneous composition can be obtained, in particular a suitable precursor granulate, with which upon selection of a suitable stoichiometry the desired silicon carbide-containing compounds can be obtained under the action of energy in additive manufacturing.

Furthermore, it may be provided that the precursor granulate by thermal treatment under reductive conditions is converted to a reduced precursor granulate. The reductive thermal treatment usually takes place in an inert gas atmosphere, wherein in particular the carbon source, preferably a sugar-based carbon source, reacts with oxides or other compounds of silicon as well as possible further compounds of other elements, whereby the elements are reduced and volatile oxidized carbon and hydrogen compounds, in particular water and CO2, are formed, which are removed via the gas phase.

Precursor granules can in particular be prepared by a sol-gel method, wherein in a first method step a solution or dispersion, in particular a sol, containing at least one silicon-containing compound, at least one carbon-containing compound, at least one solvent or dispersant, and optionally doping and/or alloying reagents, is produced, in a second method step following the first method step (i), the solution or dispersion is reacted, in particular aged to a gel, and in a third method step following the second method step (ii), the reaction product from the second method step (ii), in particular the gel, is dried and, if necessary, comminuted.

A method for producing a suitable precursor granulate for the production of silicon carbide by means of a sol-gel process is mentioned, for example, in German patent application DE 10 2015 105 085.4.

In the context of the present invention, a solution is to be understood as a single-phase system in which at least one substance, in particular a compound or its building blocks, such as ions, are homogeneously distributed in a further substance. In the context of the present invention, a dispersion is to be understood as an at least two-phase system, wherein a first phase, namely the dispersed phase, is present distributed in a second phase, the continuous phase. The continuous phase is also called dispersion medium or dispersant. In particular with sols or also with polymeric compounds, the transition from a solution to a dispersion is often fluid, so that it is no longer possible to distinguish clearly between a solution and a dispersion.

As far as the selection of the solvent or dispersant in method step (a) is concerned, this can be selected from all suitable solvents or dispersants. Usually, however, the solvent or dispersant in method step (a) is selected from water and organic solvents and mixtures thereof, preferably mixtures thereof. In particular in the case of mixtures containing water, inorganic hydroxides, in particular metal hydroxides and silicic acids, are often formed by hydrolysis reaction of the starting compounds, which subsequently condense, so that the method can be carried out in the form of either a sol-gel process or stopped at the stage of a sol.

Furthermore, it may be provided that the solvent is selected from alcohols, in particular methanol, ethanol, 2-propanol, acetone, ethyl acetate and mixtures thereof. It is particularly preferred in this context if the organic solvent is selected from methanol, ethanol, 2-propanol and mixtures thereof, wherein ethanol in particular is preferred.

The aforementioned organic solvents are miscible with water in wide ranges and in particular also suitable for dispersing or dissolving polar inorganic substances.

For producing the sol or gel, mixtures of water and at least one organic solvent, in particular mixtures of water and ethanol, are preferably used as solvents or dispersants. In this context, it is preferred if the solvent or dispersant comprises a ratio by weight of water to organic solvent of 1:10 to 20:1, in particular 1:5 to 15:1, preferably 1:2 to 10:1, more preferably 1:1 to 5:1, particularly preferably 1:3. By the ratio of water to organic solvent, on the one hand, the hydrolysis rate, in particular of the silicon-containing compound as well as of the alloying reagents, can be adjusted, and on the other hand, the solubility and reaction rate of the carbon-containing compound, in particular of the carbon-containing precursor compound, such as sugars, can also be adjusted.

Furthermore, it is preferred if in the method for producing the precursor granules in method step (i) the silicon-containing compound is selected from silanes, silane hydrolysates, orthosilicic acid as well as mixtures thereof, in particular silanes. Orthosilicic acid and also its hydrolysis products can be obtained in the context of the present invention, for example, from alkali metal silicates whose alkali metal ions have been exchanged for protons by ion exchange. However, alkali metal compounds are as far as possible not used in the context of the present invention, since these are incorporated into the resulting precursor granules in particular when a sol-gel method is used or when the sol is dried, and consequently are also found in the silicon carbide-containing compound. However, alkali metal doping is generally not desired in the context of the present invention. However, if this should be desired, suitable alkali metal salts, for example of the silicon-containing compound or also alkali phosphates, can be used.

Particularly good results are obtained if silanes, in particular tetraalkoxysilanes and/or trialkoxyalkylsilanes, preferably tetraethoxysilane, tetramethoxysilane or triethoxymethylsilane are used as the silicon-containing compound in method step (i), since these compounds react by hydrolysis in aqueous medium to give orthosilicic acids or their condensation products or highly crosslinked siloxanes and the corresponding alcohols.

As far as the carbon-containing compound is concerned, it has proven well if in method step (i) the carbon-containing compound is selected from the group of sugars, in particular sucrose, glucose, fructose, invert sugar, maltose; starch; starch derivatives and organic polymers, in particular phenol-formaldehyde resin, resorcinol-formaldehyde resin, and mixtures thereof. Particularly good results are obtained in the context of the present invention if in method step (i) the carbon-containing compound is used in an aqueous solution or dispersion.

In particular, if the carbon-containing compound is used in an aqueous solution or dispersion, the carbon-containing compound is usually introduced in a small amount of the solvent or dispersant, in particular water, intended for producing the precursor granules in method step (i). In this context, particularly good results are obtained if the carbon-containing compound is used in a solution containing the carbon-containing compound in amounts of 10 to 90 wt. %, in particular 30 to 85 wt. %, preferably 50 to 80 wt. %, in particular 60 to 70 wt. %, based on the solution or dispersion of the carbon-containing compound.

In particular, it is also possible, for example, that catalysts, in particular acids or bases, are added to the solution or dispersion of the carbon-containing compound, in order, for example, to accelerate the inversion of sucrose and to achieve better reaction results.

Now, with regard to the temperatures at which method step (i) is carried out, it has been well proven if method step (i) is carried out at temperatures in the range from 15 to 40° C., in particular 20 to 30° C., preferably 20 to 25° C.

Furthermore, it is possible that in method step (ii) the temperatures in comparison to method step (i) are slightly increased in order to accelerate the reaction of the individual components of the solution or dispersion, in particular the condensation reaction during the aging of the sol to the gel.

Particularly good results are obtained in this context if method step (ii) is carried out at temperatures in the range from 20 to 80° C., in particular 30 to 70° C., preferably 40 to 60° C. It has been proven particularly well in this context if method step (ii) is carried out at 50° C.

As far as the period of time for which method step (ii) is carried out is concerned, this can vary depending on the respective temperatures, the solvents used and the precursor compounds used. Usually, however, method step (ii) is carried out for a period of 15 minutes to 20 hours, in particular 30 minutes to 15 hours, preferably 1 to 10 hours, more preferably 2 to 8 hours, most preferably 2 to 5 hours. Within the aforementioned time periods, a complete reaction of the sol to a gel is usually observed if the method is carried out as a sol-gel process.

As far as the quantities of the individual components in method step (ii) in relation to each other are concerned, these can vary within wide ranges depending on the intended use. For example, precursor compositions for stoichiometric silicon carbide or non-stoichiometric silicon carbide comprise completely different compositions and proportions of the individual components than compositions intended for producing silicon carbide alloys.

Also, when selecting the individual compounds, in particular the doping reagents or alloying reagents, care must be taken to ensure that they can be processed into homogeneous granules with a carbon source and a silicon source which can react in additive manufacturing processes to form silicon carbide-containing compounds.

In particular, care should preferably be taken to ensure that the doping and/or alloying reagents are decomposed or cleaved under the action of energy in such a way that the desired elements de-sublimate as reactive particles to form the desired alloy, while the remaining constituents of the compound react as far as possible to form stable gaseous substances, such as water, CO, CO2, HCl, etc., which can be easily removed via the gas phase. Furthermore, the compounds used should comprise sufficiently high solubilities in the solvents used, in particular in ethanol and/or water, to be able to form finely divided dispersions or solutions, in particular sols, and may not react with other constituents of the solution or dispersion, in particular the sol, to form insoluble compounds during the production process. In addition, the reaction rates of the individual reactions taking place must be coordinated with each other, since hydrolysis, condensation and, in particular optionally gelation must proceed undisturbed in the run-up to granule formation. Furthermore, the reaction products formed may not be sensitive to oxidation and should not be volatile.

Furthermore, it may be provided that the solution or dispersion contains at least one doping and/or alloying reagent. If the solution comprises a doping and/or alloying reagent, it has been well proven if the solution or dispersion comprises the doping or alloying reagent in amounts of 0.000001 to 60 wt. %, in particular 0.000001 to 45 wt. %, preferably 0.000005 to 45 wt. %, more preferably 0.00001 to 40 wt. %, based on the solution or dispersion.

If the solution or dispersion comprises a doping reagent, the solution or dispersion typically comprises the doping reagent in amounts of 0.000001 to 0.5 wt. %, preferably 0.000005 to 0.1 wt. %, more preferably 0.00001 to 0.01 wt. %, based on the solution or dispersion.

If the solution or dispersion contains an alloying reagent, it is usually provided that the solution or dispersion contains the alloying reagent in amounts of 5 to 60 wt. %, in particular 10 to 45 wt. %, preferably 15 to 45 wt. %, more preferably 20 to 40 wt. %, based on the solution or dispersion.

Now, as far as the chemical nature of the doping reagent is concerned, this may be selected from the previously mentioned compounds.

If the solution or dispersion contains an alloying reagent, the alloying reagent is usually selected from soluble in the solvent or dispersant compounds of Al, Ti, V, Cr, Mn, Co, Ni, Zn, Zr and their mixtures. According to a more preferred embodiment of the present invention, the alloying reagent is selected from chlorides, nitrates, acetates, acetylacetonates and formates of Al, Ti, V, Cr, Mn, Co, Ni, Zn, Zr and mixtures thereof.

If a stoichiometric silicon carbide SiC, which is optionally doped, is to be obtained, particularly good results are achieved if the solution or dispersion in the first method step contains the silicon-containing compound in amounts of 10 to 40 wt. %, in particular 12 to 30 wt. %, preferably 15 to 25 wt. %, more preferably 17 to 20 wt. %, based on the solution or dispersion.

Similarly, according to this embodiment, it may be provided that the solution or dispersion comprises the carbon-containing compounds in amounts of 6 to 40 wt. %, in particular 8 to 30 wt. %, preferably 10 to 25 wt. %, more preferably 12 to 20 wt. %, based on the solution or dispersion.

In addition, according to this embodiment, it may be provided that the solution or dispersion comprises the solvent or dispersant in amounts of 20 to 80 wt. %, in particular 30 to 70 wt. %, preferably 40 to 60 wt. %, more preferably 45 to 55 wt. %, based on the solution or dispersion.

If the silicon carbide is to be doped, the solution or dispersion typically contains the doping reagent in amounts of 0.000001 to 0.5 wt. %, in particular 0.000005 to 0.1 wt. %, preferably 0.00001 to 0.01 wt. %, based on the solution or dispersion.

If a non-stoichiometric silicon carbide is to be obtained, in particular with a molecular excess of silicon, it has been well proven if the solution or dispersion in the first method step (a) contains the silicon-containing compound in amounts of 12 to 40 wt. %, in particular 15 to 40 wt. %, preferably 18 to 35 wt. %, more preferably 20 to 30 wt. %, based on the solution or dispersion.

According to this embodiment, it may further be provided that the solution or dispersion comprises the carbon-containing compound in amounts of 6 to 40 wt. %, in particular 8 to 30 wt. %, preferably 10 to 25 wt. %, more preferably, 12 to 20 wt. %, based on the solution or dispersion.

Furthermore, in accordance with this embodiment, it may equally be envisaged that the solution or dispersion contains the solvent or dispersant in amounts of 20 to 80 wt. %, in particular 30 to 70 wt. %, preferably 40 to 60 wt. %, more preferably 45 to 55 wt. %, based on the solution or dispersion.

If the non-stoichiometric silicon carbide is to be doped, it has been well proven if the solution or dispersion contains the doping reagent in amounts of 0.000001 to 0.5 wt. %, preferably 0.000005 to 0.1 wt. %, more preferably 0.00001 to 0.01 wt. %, based on the solution or dispersion.

If a silicon carbide alloy is to be produced, it has proven useful if the solution or dispersion in the first method step (a) contains the silicon-containing compound in amounts of 5 to 30 wt. %, in particular 6 to 25 wt. %, preferably 8 to 20 wt. %, more preferably 10 to 20 wt. %, based on the solution or dispersion.

Similarly, according to this embodiment, it is preferred if the solution or dispersion comprises the carbon-containing compound in amounts of 5 to 40 wt. %, in particular 6 to 30 wt. %, preferably 7 to 25 wt. %, more preferably, 10 to 20 wt. %, based on the solution or dispersion.

Furthermore, according to this embodiment, it is preferred if the solution or dispersion contains the solvent or dispersant in amounts of 20 to 70 wt. %, in particular 25 to 65 wt. %, preferably 30 to 60 wt. %, more preferably 35 to 50 wt. %, based on the solution or dispersion.

It is advantageously provided that the solution or dispersion contains the alloying reagent in amounts of 5 to 60 wt. %, in particular 10 to 45 wt. %, preferably 15 to 45 wt. %, more preferably 20 to 40 wt. %, based on the solution or dispersion.

Particularly preferably, the alloying reagent is selected from the corresponding chlorides, nitrates, acetates, acetylacetonates and formates of the corresponding alloying elements.

As far as the performance of method step (iii) is concerned, it has been well proven if in method step (iii) the reaction product from method step (ii) is dried at temperatures in the range from 50 to 400° C., in particular 100 to 300° C., preferably 120 to 250° C., more preferably 150 to 200° C.

In this context, it has been well proven if the reaction product in method step (iii) is dried for a period of 1 to 10 hours, in particular 2 to 5 hours, preferably 2 to 3 hours.

In addition, it is possible for the reaction product to be comminuted in method step (iii), in particular following the drying process. In this context, it is preferred in particular if the reaction product is mechanically comminuted in method step (iii), in particular by grinding. Grinding processes can be used to specifically adjust the required or advantageous particle sizes for carrying out additive manufacturing processes. However, it is often also sufficient to mechanically stress the reaction product from method step (ii) during the drying process, for example by stirring, in order to set the desired particle sizes.

Preferably, in a fourth method step (iv) following method step (iii), the composition obtained in method step (iii) is subjected to a reductive thermal treatment so that a reduced composition is obtained. The use of a reduced composition which has been subjected to a reductive treatment has the advantage that a large number of possible and interfering by-products have already been removed. The resulting reduced precursor granulate is again significantly more compact and contains higher proportions of the elements that form the silicon carbide-containing compound.

If, following method step (iii), a reductive thermal treatment of the composition obtained in method step (iii) is carried out, it has been well proven if, in method step (iv), the composition obtained in method step (iii) is heated to temperatures in the range from 700 to 1,300° C., in particular 800 to 1,200° C., preferably 900 to 1,100° C.

In this context, particularly good results are obtained if the composition obtained in method step (iv) is heated for a period of 1 to 10 hours, in particular 2 to 8 hours, preferably 2 to 5 hours. In the temperature ranges and the reaction times mentioned, carbonization of the carbonaceous precursor material can take place in particular, which can significantly facilitate the subsequent reduction, in particular of metal compounds.

In general, method step (iv) is carried out in a protective gas atmosphere, in particular in an argon and/or nitrogen atmosphere. In this way, oxidation in particular of the carbon-containing compound is prevented.

If the reductive thermal treatment of the precursor granules described above is provided in order to obtain a reduced precursor granule, the precursor compounds may not evaporate at the applied temperatures of up to 1,300° C., preferably up to 1,100° C., but must specifically decompose under the reductive thermal conditions to form compounds which can be specifically converted during production to the desired silicon carbide-containing compounds.

Alternatively, the method for producing a precursor granulate can also be carried out in such a way that in a first method step, a solution or dispersion, in particular a sol, containing the components at least one silicon-containing compound, at least one carbon-containing compound, at least one solvent or dispersant, and optionally doping and/or alloying reagents, is produced, and in a second method step following the first method step (i), the solvent or dispersant is removed.

For, as was surprisingly found, it is often possible to dispense with carrying out a sol-gel method. In particular, comparable precursor granules can often be obtained if the solvent or dispersant is removed after sol formation, for example under vacuum.

The precursor granules obtained in this way can be converted into reduced precursor granules by temperature treatment in the range from 400 to 800° C. The precursor granules obtained after sol formation by removing the solvent or dispersant correspond in their percentage distribution of the contained elements to the precursor granules obtained by a sol-gel method and can be processed like these.

A further subject-matter of the present invention—according to a second aspect of the present invention—is a structured or surface-modified silicon carbide-containing article, in particular comprising silicon carbide-containing material or consisting of silicon carbide-containing material, which is obtainable by the method described above.

The structured or surface-modified silicon carbide-containing articles according to the invention are characterized in particular by the fact that the silicon carbide-containing article can either comprise different chemical compositions or comprise structured, in particular microstructured surfaces.

For further details on this aspect of the invention, reference can be made to the above explanations on the method according to the invention, which apply accordingly with respect to the structured or surface-modified silicon carbide-containing article according to the invention.

Again, another subject-matter of the present invention—according to a third aspect of the present invention—is an apparatus for carrying out the aforementioned method, wherein the apparatus comprises at least one device for producing silicon carbide-containing articles by means of additive manufacturing from precursor materials, comprising at least a carbon source and at least a silicon source, and at least one device for generating laser beams, in particular at least one laser, for processing at least a surface of a silicon carbide-containing article.

The silicon carbide-containing substrate may either be the finished silicon carbide-containing article or also intermediate stages during additive manufacturing.

In accordance with one embodiment of the present invention, the device for producing three-dimensional articles from silicon carbide-containing materials by means of additive manufacturing is configured in such a way that it comprises a device for producing laser beams, in particular at least one laser. The laser is then used to decompose the precursor materials in a site-selective manner, so that silicon carbide-containing materials are applied to a substrate surface in a site-selective manner and in layers.

The device for producing three-dimensional articles from silicon carbide-containing materials is preferably a device for selective synthetic crystallization, a device for carrying out printing processes, in particular inkjet processes, with subsequent laser-induced decomposition of the precursor materials, or a device for laser deposition welding.

Usually, the apparatus for carrying out the method further comprises at least one device for providing a layer of a precursor material or at least one device for applying precursor materials to a substrate or a device for generating a particle stream, in particular of the precursor materials or their decomposition products.

The apparatus according to the invention for generating laser beams for processing the surfaces of a silicon carbide-containing substrate is based on conventional apparatuses for laser ablation, but is specially configured for processing silicon carbide-containing materials. This applies in particular with regard to the lasers used.

With the apparatus according to the present invention, not only ablation of silicon carbide-containing surfaces can be carried out, but it is also possible to manipulate the chemical modification of silicon carbide-containing surfaces in a targeted manner, in particular by creating defects on the surface by means of exposure to laser radiation and subsequent doping of the surface.

If, in the context of the present invention, the apparatus is to be used to thermally treat, i.e., to heat, the surface of the silicon carbide-containing article or of the partially produced silicon carbide-containing article as part of the surface treatment, it is often sufficient if the apparatus comprises a device for generating laser beams, in particular the device for generating laser beams which is used to carry out the additive manufacturing process.

However, if the apparatus is to be used to perform ablation by Coulomb explosion, the apparatus typically comprises multiple, in particular at least two, devices for generating laser beams.

Furthermore, it may be provided in the context of the present invention that the apparatus comprises means for contacting doping reagents with an optionally chemically modified surface of a silicon carbide-containing material. Such means may be, for example, in the form of nozzles for spraying the chemically modified or activated silicon carbide-containing surface of the substrate, in particular the silicon carbide-containing article. In addition, however, it is also possible that the doping reagents are contained in the process atmosphere

With the apparatus according to the invention, it is in particular possible to selectively dope doped regions which comprise expansions in one or two spatial directions of only a few micrometers. It is also possible to selectively dope silicon carbide-containing materials subsequently.

Furthermore, it may be provided within the scope of the present invention that the apparatus comprises means for generating a process atmosphere, in particular an inert gas atmosphere, and/or means for generating a vacuum. As previously stated, in the context of the present invention, the method is typically carried out in an inert gas atmosphere or in a vacuum.

Furthermore, it may equally be provided that the apparatus comprises means for measuring the surface of the silicon carbide-containing material. In this context, it can be provided in particular that the apparatus comprises an interferometer which registers the reflected laser beam and makes it possible to monitor the performance of the method simultaneously, i.e. in situ, and to adjust the laser power and the point of impact of the laser on the silicon carbide-containing article or substrate in a targeted manner.

For further details on this aspect of the invention, reference can be made to the above explanations on the further aspects of the invention, which apply accordingly with respect to the apparatus according to the invention

The subject-matter of the present invention is illustrated below in a non-limiting manner by way of example in the figures.

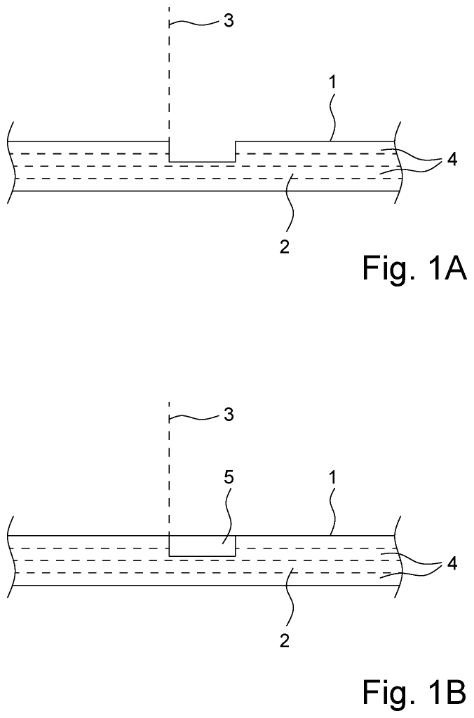

FIG. 1A shows a simplified section of the implementation of a method step of the method according to the invention in the form of ablation. The surface 1 of a silicon carbide-containing article 2, which has been produced by additive manufacturing in the form of layers 4, is irradiated by a laser beam 3 in such a way that material is removed from the surface 1. The material is removed either thermally by sublimation or by Coulomb explosion. When performing the ablation, it is possible to structure the surface 1 or to give the silicon carbide-containing article 2 a shape or to rework the intended shape of the silicon carbide-containing material, i.e. to process the silicon carbide-containing article 2 geometrically.

By selectively controlling the laser power, the material removal from the surface 1 of the silicon carbide-containing article 2 can be selectively adjusted. In particular, it is also possible to process certain areas of the surface several times in order to avoid applying too much energy to the surface in a single operation, thus causing material removal or material change in areas where this is not intended.

Within the scope of the method according to the invention, a precise removal of material in the nano- or micrometer range is possible, whereby in particular nano- and micro structuring of surfaces is possible, but also edges or contours of objects can be reworked. Similarly, it is possible to remove artifacts created during additive manufacturing, such as support structures, or to smoothen surfaces, for example to smooth the layered structure from additive manufacturing that is often still visible at the interfaces of a body, so that a homogeneous smooth surface is created.

FIG. 1B shows the implementation of a surface treatment carried out in the process according to the invention by chemical modification of a surface 1 of a silicon carbide-containing article 2. Here, the surface 1 of the silicon carbide-containing article 2 is irradiated by means of a laser beam 3, preferably at temperatures in the range of 500 to 1,800° C., whereby a change in the chemical structure of the silicon carbide-containing material is obtained in irradiated areas and a chemically modified area 5 is created. In particular, it is possible in this way to enrich surfaces with carbon or silicon or to carry out locally limited doping in a targeted manner.

As previously explained, the present invention combines a method for processing surfaces of silicon carbide-containing materials with additive manufacturing processes. For example, a surface 1 of a silicon carbide-containing article 2 can be obtained by additive manufacturing and then the surface 1 can be processed by exposure to laser radiation, wherein either ablation or chemical modification of the surface is performed. Then, in turn, another layer 4 of the silicon carbide-containing material can be applied by additive manufacturing.

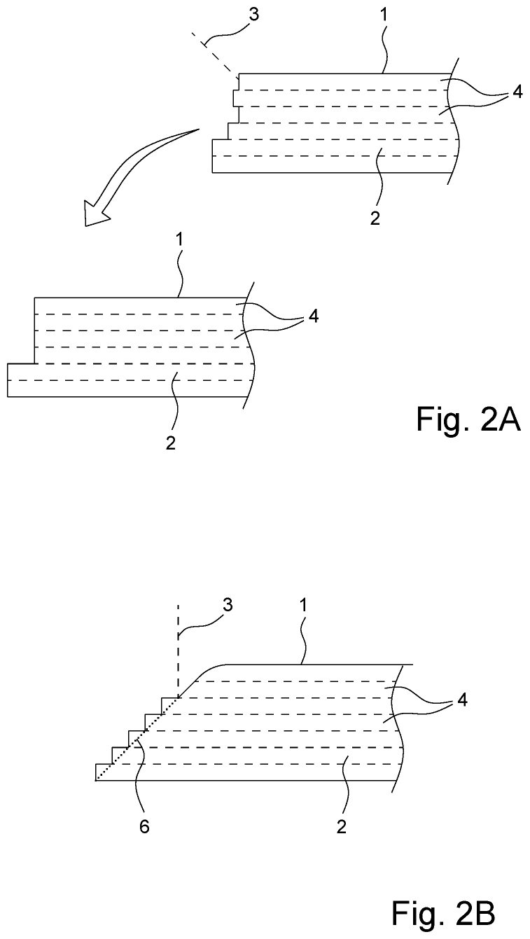

FIGS. 2A and 2B show examples of applications for the combination of additive and subtractive manufacturing, in particular for the processing of an article 2 containing silicon carbide produced by additive manufacturing by means of ablation. FIG. 2A shows a silicon carbide-containing object 2 with a surface 1, which was built up using additive manufacturing in the form of layers 4. The layered structure of the silicon-carbide-containing material 2 produces rough surfaces at the interface of the individual layers, which are caused by the fact that a small offset can form between the individual layers. Treatment of this uneven surface 1 by means of a laser beam 3 then produces a surface that is even also in the micro- or nanometer range.

FIG. 2B shows the geometric post-processing of a silicon carbide-containing article 2 produced by additive manufacturing by ablation using a laser beam 3. The silicon carbide-containing article 2 is built up in layers by additive manufacturing, in particular in the form of the layers 4, and has a surface 1 which comprises a step-like structure due to the resolution of the additive method used. Since, prior to producing the silicon carbide-containing article 2, a digital image, in particular a digital twin, of the silicon carbide-containing article 2 to be produced, the contour sharpness or resolution of which can be adjusted almost at will, the surface 1 of the silicon carbide-containing article 2 can be easily and simply reworked within the scope of the present invention by means of the laser beam 3. In FIG. 2B, the silicon carbide-containing article 2 is superimposed on the digital image and the laser beam 3 removes the material of the silicon carbide-containing article 2 along the cutting line given by the projection 6 of the digital image. The method according to the invention thus provides significantly better and higher resolution silicon carbide-containing articles than purely additive methods.

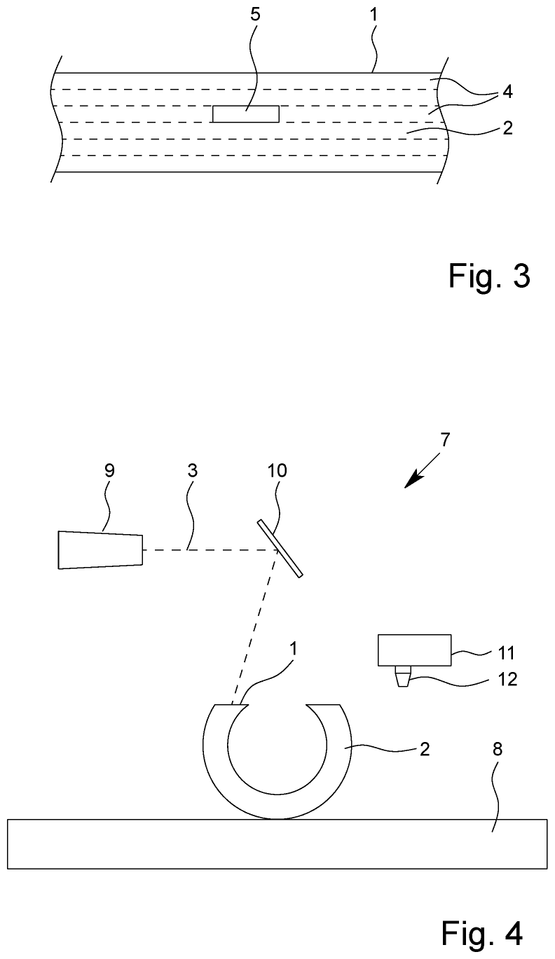

FIG. 3 shows a silicon carbide-containing article 2 with a surface 1 which was successively built up by means of additive manufacturing by applying layers 4. A surface treatment by means of chemical modification created a chemically modified area 5, in particular an area provided with a doping element, onto which further layers 4 of silicon carbide-containing material were subsequently applied by means of additive manufacturing. In this way it is possible to create areas with different electrical properties on the surface or in the structure of a silicon carbide-containing article 2. Here it is possible, for example, to structure or smoothen surfaces, in particular during the producing of a silicon carbide-containing article, which after producing are enclosed by parts of the silicon carbide-containing article obtained in such a way that they are no longer accessible for surface processing. Also, defects occurring during additive manufacturing or process-related lower resolutions can be reworked immediately so that surfaces with high contour sharpness are obtained.

The method according to the invention is preferably carried out with additive manufacturing processes that work with lasers. In this way, it is often possible to use a laser to perform both additive manufacturing and surface processing, in particular ablation or chemical modification of the surface.

FIG. 4 shows an example of an apparatus 7 for producing silicon carbide-containing materials from liquid precursors, as known from DE 10 2017 110 361 A1.

With the apparatus according to FIG. 4, three-dimensional silicon carbide-containing articles 2 with surfaces 1 can be created, which can be processed with laser radiation 3.

For additive manufacturing, the apparatus 7 comprises a building field 8 on which an article 2 made of silicon carbide-containing material is built. The apparatus 5 comprises in particular a discharge device 11 with application means 12, in particular one or more nozzles for discharging a solution or dispersion containing precursors, in particular a precursor sol. Usually it is now provided that either the construction field 8 or the discharge device 11 are movable, in particular movable in an xy-plane, preferably movable in x-, y- and z-direction. Here, it is usually provided that only the discharge device 11 or the construction field 8 is movable. Similarly, it may also be provided that the discharge device 11 is movable in the xy plane, while the building field 8 is movable in the z direction, so that a layer-by-layer build-up of the silicon carbide-containing article 2 is made possible.

The discharge device 11, in particular the build field 8, is thereby configured such that a solution or dispersion is applied to a substrate, in particular a silicon carbide-containing article 2 or a build field 8, in a site-selective and locally limited manner by an inkjet printing process.

The apparatus 7 further typically comprises means for generating laser beams 9, in which laser beams 3 are generated, and deflection means 10 for deflecting laser beams, in particular a mirror arrangement. In addition, however, other setups are also possible, such as comprising means for generating laser beams and other means for directing laser beams, in particular, for example, at least one light guide with which the laser beam can be directed onto the corresponding surface to be irradiated.

In additive manufacturing, the procedure is preferably such that by means of the discharge means 11, in particular the application means 12, a solution or dispersion containing a suitable precursor is applied to the building area 8 or the silicon carbide-containing article 2 and is then selectively decomposed by means of laser beams 3, so that silicon carbide-containing materials are obtained. In this way, an article 2 comprising silicon carbide-containing material can be obtained successively layer by layer by means of additive manufacturing. Within the scope of the invention, it is now possible to process the surfaces 1 of the silicon carbide-containing article 2 during additive manufacturing or subsequently to additive manufacturing by means of laser beams 3, as previously explained.

Preferably, the same means 9 for generating laser beams and the same deflection means 10 which are also used for additive manufacturing are used for surface processing for this purpose. Alternatively, however, it is also possible for the further means for generating laser beams to be used specifically for surface processing, in particular for ablation or for chemical modification of the surface 1 of the silicon carbide-containing article 2.

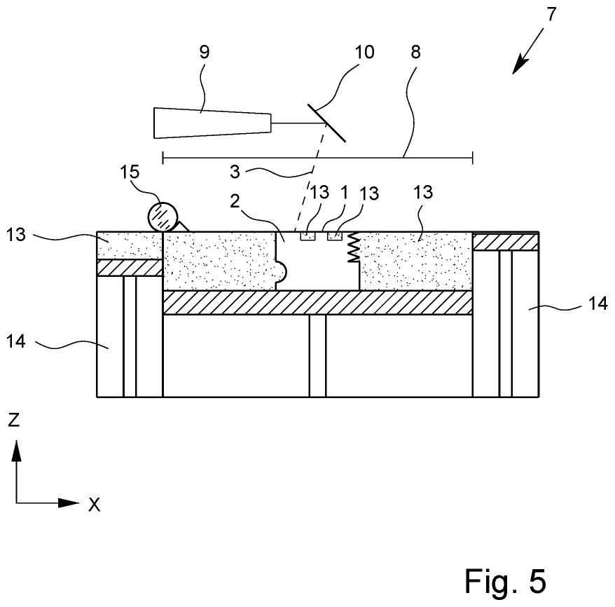

FIG. 5 shows a further variant of additive manufacturing, such as that illustrated in DE 10 2017 110 362 A1.

Here, an article 2 made of silicon carbide-containing material with a surface 1 is obtained by means of a powder bed process.

The apparatus 7 shown in FIG. 5 likewise comprises means for generating laser beams 9 and deflection means for deflecting laser radiation 10.

Furthermore, the apparatus 7 comprises a building field 8 on which the article 2 is produced from silicon carbide-containing material. Here, a precursor material 13, in particular a powdery composition, is distributed in particular on the building field 8 and is selectively irradiated with laser beams 3 in order to produce a layer of a silicon carbide-containing object.

Subsequently, further precursor material 13 is distributed homogeneously and with a constant layer thickness on the building field 8 from a storage device 14 by means of a distribution device 15 and this layer is again irradiated selectively with laser beams 3.

The build field area can be moved in particular in the z-direction, preferably by means of a piston.

By repeatedly carrying out the method described above, a three-dimensional article 2 made of silicon carbide-containing material is finally obtained.

Here it can now be equally provided that surfaces 1 of the silicon carbide-containing material 2 are treated before applying further layers by means of ablation or chemical modification of the surface by irradiation with laser radiation 3 as previously described.

In accordance with this embodiment of the present invention, it is more preferably the case that the complete article is produced first, and then the powder bed of precursor material 13 is removed, before any processing of the surfaces 1 of the silicon carbide-containing article 2 is carried out.

In addition, as previously explained, it is equally possible to carry out additive manufacturing within the scope of the present invention in the form of a process control based on laser deposition welding.

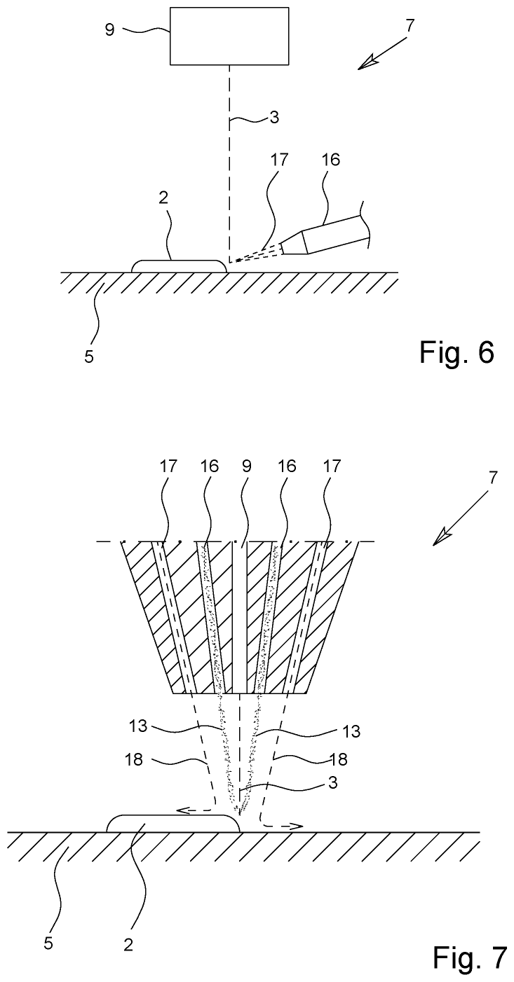

FIG. 6 shows an apparatus 7 for additive manufacturing of silicon carbide-containing articles 2 by means of laser deposition welding. The apparatus 7 according to FIG. 6 comprises means 9 for generating laser beams 3 and at least one device 16 for generating a particle beam from gaseous, liquid or solid precursor materials 13. Preferably, the particle beam is formed by powdery precursor materials 13. The laser beams 3 and the particle beam of the precursor material 13 are directed onto the surface of a substrate 5 in such a way that the laser beams 3 strike the particle beam in the immediate proximity in front of the substrate surface. As a result, the precursor materials 13 contained in the particle beam are decomposed or gasified, whereby reactive fragments are obtained and the desired silicon carbide material is deposited on the substrate surface in the form of a silicon carbide-containing article 2.

FIG. 7 shows an additive configuration of the apparatus 7 for additive manufacturing by means of laser deposition welding; in particular, FIG. 7 shows a section of an apparatus 7. The apparatus 7 comprises a device 9 for generating laser beams with which precursor materials 13 can be gasified and decomposed. Furthermore, the apparatus 7 according to this embodiment comprises devices 16 for generating a particle beam from preferably powdery precursor materials 13. In the embodiment of the apparatus 7 shown in FIG. 7, the devices 9 and 16 are jointly integrated in a device, in particular a nozzle head, which is preferably designed to be movable.

The particle beam from the precursor material 13, in particular the particle beams, surround the laser beam 3 and cross the latter shortly before impinging on the surface of a substrate, as a result of which the precursor materials 13 are decomposed and a layer of a silicon carbide-containing article 2 is deposited on the substrate surface.

The apparatus 7, according to this embodiment, in particular further comprises means 17 for generating a protective gas atmosphere, in particular a stream of protective gas 18. The stream of protective gas 18 thereby surrounds or envelops the particle beam or beams of precursor material 13 and thus enables decomposition of the precursor materials 13 in a protective gas atmosphere, in particular an argon atmosphere.

Not shown in the figures are alternative and equally preferred embodiments in which for the additive manufacturing and the subtractive manufacturing or the chemical modification of the surface of silicon carbide-containing materials by means of laser radiation different devices for generating laser beams, in particular pulse lasers, are used.

In particular, it may be provided in the context of the present invention that for the subtractive method, an ultrashort pulse laser, in particular an excimer laser, with radiation in the UV range is used, which is usually not suitable for additive manufacturing. In this case, the apparatus 7 must comprise at least two different devices 9 for generating laser beams 3.

### REFERENCE SIGNS

1 surface
2 silicon carbide-containing article
3 laser beam
4 layer
5 chemically modified area
6 projection digital image
7 apparatus
8 building field
9 means for generating laser beams
10 deflection means
11 discharge device
12 application means
13 precursor material
14 storage device
15 distribution device
16 device for generating a particle beam
17 means for generating a protective gas atmosphere
18 stream of protective gas

1-20. (canceled)

21. A method for making an article comprising silicon carbide, the method comprising:
producing an article comprising silicon carbide via additive manufacturing; and
heating via at least one laser beam in a site-selective and locally limited manner a surface of the article so as to cause at least one of ablation and chemical modification of the surface.

22. The method according to claim 21, where the silicone carbine is at least one of silicon carbide, doped silicon carbide, non-stoichiometric silicon carbide, doped non-stoichiometric silicon carbide and silicon carbide alloys.

23. The method according to claim 21, wherein the additive manufacturing includes laser radiation.

24. The method according to claim 21, wherein the additive manufacturing includes at least one of selective synthetic crystallization, printing methods with subsequent heating, and laser deposition welding.

25. The method according to claim 21, further comprising, prior to producing the article, creating a digital image of the article using CAD.

26. The method according to claim 25, wherein the article is produced by alignment with the digital image.

27. The method according to claim 21, further comprising measuring the article at least one of during and after the additive manufacturing.

28. The method according to claim 21, wherein the surface of the article is heated to a temperature from 500 to 3,500° C.

29. The method according to claim 21, wherein the surface is ablated and the ablation is at least one of structured and smoothened.

30. The method according to claim 29, wherein the surface is heated to a temperature above 2,200° C.

31. The method according to claim 21, wherein the surface of the article is chemically modified to have at least one of an enrichment of silicon on the surface, an enrichment of carbon on the surface, production of graphene on the surface, production of graphite on the surface, and production of silicon dioxide on the surface.

32. The method according to claim 31, wherein the surface is heated to a temperature above 500° C.

33. The method according to claim 31, wherein the chemical modification includes at least one of the enrichment of silicon and the enrichment of carbon on the surface, and wherein the surface is activated for doping with doping reagents.

34. The method according to claim 21, wherein the at least one laser beam is generated by a pulse laser.

35. The method according to claim 21, wherein the at least one laser beam comprises a wavelength in the visible range or in the IR range.

36. The method according to claim 21, wherein the at least one laser beam comprises a wavelength in the UV range to cause the ablation.

37. The method according to claim 21, further comprising continuously monitoring the article during the ablation.

38. A particular article made by the method of claim 21.

39. An apparatus for making an article comprising silicon carbide, the apparatus comprising:
an additive manufacturing device for producing an article comprising silicon carbide from precursor materials, the precursor materials comprising at least a carbon source and at least a silicon source; and
at least one laser for generating a laser beam, wherein the laser is configured such that the laser beam heats at least a surface of the article.

40. The apparatus according to claim 39, further comprising at least one of an inert gas source and a vacuum, wherein the apparatus is configured such that the article is produced in an inert gas atmosphere or in a vacuum atmosphere, respectively.
